(19) United States
(12) Patent Application Publication
(10) Pub. No.: US 2010/0101494 A1
(43) Pub. Date: Apr. 29, 2010

(54) ELECTRODE AND CHEMICAL VAPOR DEPOSITION APPARATUS EMPLOYING THE ELECTRODE

(76) Inventors: Jui Hai (Harry) Hsieh, Hsinchu City (TW); David DeLong, Austin, TX (US)

Correspondence Address: Zarian Midgley & Johnson PLLC, University Plaza, 960 Broadway Ave., Suite 250, Boise, ID, 83706, US

(21) Appl. No.: 12/607,860

(22) Filed: Oct. 28, 2009

Related U.S. Application Data
(60) Provisional application No. 61/109,137, filed on Oct. 28, 2008.

(51) Int. Cl. C23C 16/46; B23P 6/00

(52) U.S. Cl. 118/725; 29/402.08

(57) ABSTRACT

A chemical vapor deposition apparatus is disclosed. The chemical vapor deposition apparatus comprises a chamber having a base plate, a chamber wall, a gas inlet, a gas outlet and a plurality of electrodes each comprising an electrode body and an electrode cap removably attached to the electrode body. The electrode body can be positioned through the base plate. The cap can be positioned inside the chamber. An electrical isolation layer is positioned between the electrode and the base plate. The plurality of electrodes are capable of being attached to a power source. At least two of the plurality of electrodes are capable of being electrically coupled to a silicon rod positioned in the chamber.

### RELATED APPLICATIONS

The present application claims benefit of U.S. Provisional Patent Application No. 61/109,137, filed on Oct. 28, 2008, which is incorporated herein by reference in its entirety.

### BACKGROUND

1. Field of the Disclosure

The present disclosure relates generally to electrodes, such as electrodes employed in CVD reactors.

2. Description of the Related Art

A popular method of manufacturing high purity polycrystalline silicon is through the use of a CVD reactor. FIG. 1 illustrates an example of a CVD reactor employed in such methods, which is known as a “Siemens Reactor”. During the manufacture of silicon in CVD reactors, a CVD reaction takes place on silicon rods which are heated to high temperatures, such as, for example, temperatures of about 1100° C. or more. The heat up is accomplished via electrical power introduced into the chamber through vertical stand electrodes 4, which conduct electrical current and heat up the silicon rods 2. The rods are exposed to a reaction gas which is typically a mixture of hydrogen and a silicon source gas. A common silicon source for this application is Trichlorosilane (TCS). Other well known source gases include monosilane and triethoxysilane.

Vertical stand electrodes 4 can be designed to conduct high levels of power into the CVD reactor chamber. These electrodes are often made of oxygen-free copper. Their complex design accommodates several functions, including conductance of high electrical current, acceptance of high voltage contacts, as well as adequate cooling water flow. The cooling water can have any suitable flow rate that maintains a low enough electrode temperature to avoid substantially melting an insulation material 6, typically PTFE. The insulation material is positioned on the outside of the electrode, as shown in FIG. 2. The insulation material works as electrical isolation, as well as a vacuum seal. The electrode can use a graphite adapter 8 on the top of electrode to link the silicon rod 2 and copper electrode 4.

Because the top of the electrode 4 is exposed to the working area of the chamber, it can easily be damaged by either surface micro arcing or physical damage during the harvest of polysilicon. With the design of FIG. 2, when damage occurs to the electrode top, the entire electrode is replaced. The electrode replacement process consumes a 24-hour period in the best case. Replacement of the electrode has a ripple effect to the cost of operation, as well as the production revenue. The electrode is an expensive part and is labor intensive to replace, while the unscheduled down time causes loss of production time and unrecoverable loss of revenue.

A second disadvantage of the design of FIG. 2 is related to the addition of isolation materials below the electrode top. In the industry, it is desirable to attain high power through the electrodes up to 15 KV. With this added electrical isolation, removal of the entire electrode may be necessary with the design of FIG. 2 in the event of a failure of the isolation mechanism. The benefit of moving to a higher electrical source is to reduce the heat-up time for the chamber and improve productivity.

Because the isolation material will be exposed to very high temperatures, the use of fragile materials such as quartz or ceramic can be desirable. Because the isolation material can be fragile, ease of replacement would be an advantage.

The present disclosure is directed to overcoming, or at least reducing the effects of, one or more of the issues set forth above.

### SUMMARY

An embodiment of the present disclosure is directed to a chemical vapor deposition apparatus. The chemical vapor deposition apparatus comprises a chamber having a base plate, a chamber wall, a gas inlet, a gas outlet and a plurality of electrodes each comprising an electrode body and an electrode cap removably attached to the electrode body. The electrode body can be positioned through the base plate. The cap can be positioned inside the chamber. An electrical isolation layer is positioned between the electrode and the base plate. The plurality of electrodes are capable of being attached to a power source. At least two of the plurality of electrodes are capable of being electrically coupled to a silicon rod positioned in the chamber.

The present disclosure is also directed to a vertical stand electrode. The electrode comprises an electrode body and an electrode cap removably attached to the body.

The present disclosure is also directed to a method of repairing an electrode in a chemical vapor deposition apparatus. The electrode comprises an electrode body positioned in the chemical vapor deposition apparatus. An electrode cap is removably attached to the body. The method comprises removing the electrode cap from the electrode body; and attaching a new electrode cap to the electrode body.

### BRIEF DESCRIPTION OF THE DRAWINGS

FIG. 1 illustrates a schematic drawing of a CVD apparatus.

FIG. 2 illustrates a prior art CVD electrode.

FIGS. 3 to 5 illustrate CVD electrodes, according to embodiments of the present disclosure.

FIGS. 6A and 6B illustrate a mechanism for attaching a top portion of a CVD electrode to a bottom portion, according to an embodiment of the present disclosure.

FIG. 7 illustrates a chemical vapor deposition apparatus, according to an embodiment of the present disclosure

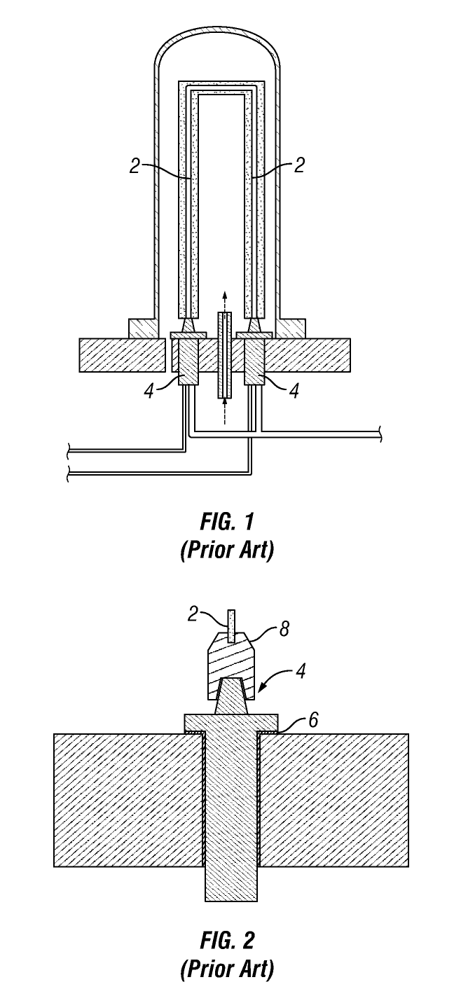

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the spirit and scope of the invention as defined by the appended claims.

### DETAILED DESCRIPTION

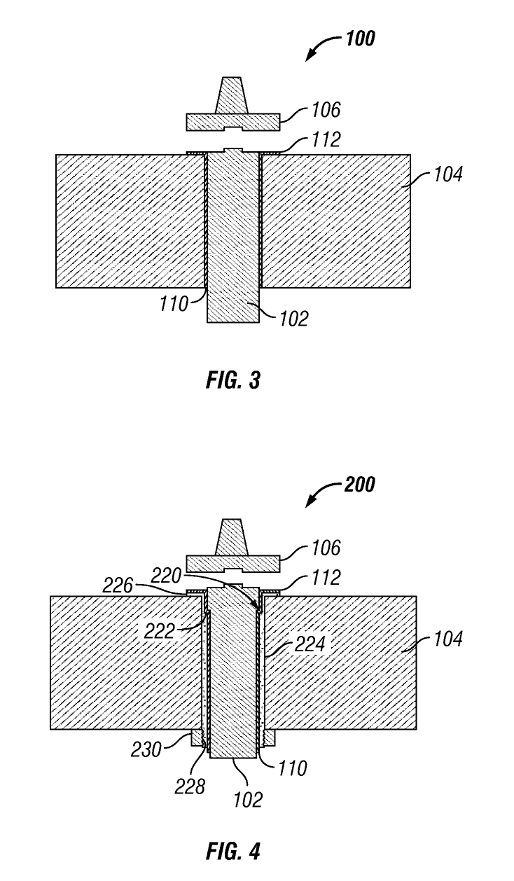

FIG. 3 illustrates an electrode 100, according to an embodiment of the present application. The electrode includes an electrode body 102 that is positioned in a base plate 104 of a chemical vapor deposition apparatus. An electrode cap 106 is removably attached to the body 102. If desired, an adapter 108 (shown in FIG. 6B) can be positioned on the electrode cap 106. The adapter 108 can comprise any suitable material, such as, for example, high purity graphite or high purity silver. Electrode 100 can also include an electrical isolation layer 110 that is positioned around the electrode body 102.

The electrode body 102 can have any design that is suitable for use with a CVD deposition apparatus. In an embodiment, the electrode body 102 can have a cylindrical shape, but other shapes can also be employed.

The electrode body 102 can be made of any suitable electrically conductive material. Examples of such material include oxygen free copper, copper alloys, silver, silver alloys and graphite. The electrode body 102 can be coated with additional materials, as illustrated by layer 454 of FIGS. 6A and 6B, which will be discussed in greater detail below.

The electrode cap 106 can be designed to cover the surface of the electrode body 102 that would otherwise be exposed to the deposition process inside a CVD chamber. As discussed above, the surface of the electrode 100 can be easily damaged during chemical vapor deposition and/or the harvesting of silicon from the CVD apparatus. The ability to remove the electrode cap 106 is advantageous because the cap 106 sustains the damage that occurs to the electrode 100 inside the CVD apparatus. This allows the cap 106 to be replaced without having to replace to entire electrode.

The electrode cap 106 can be made of any suitable electrically conductive material. Examples of such material include oxygen free copper, silver alloys, and copper alloys. The cap can be coated with a metal coating material, which can be, for example, silver, silver alloys, nickel, nickel alloys, tin, tin alloys, gold and gold alloys. For example, the electrode cap 106 can comprise oxygen free copper coated with silver, or any of the other metal coating materials listed. An example of a cap coating is layer 452 of FIGS. 6A and 6B, which will be discussed in greater detail below.

The electrical isolation layer 110 that is positioned around the electrode body 102 can include a sleeve portion that surrounds the electrode body 102 and a ring portion 112 that surrounds the mouth of the opening in the base plate 104. The electrical isolation layer 110 can be made of any suitable insulation material and can have any suitable thickness that will provide the desired insulative properties. Suitable insulating materials can withstand relatively high processing temperatures while still providing the desired electrical insulation. Examples of suitable insulation material can be polytetrafluoroethylene (“PTFE”), ceramic and quartz.

FIG. 4 illustrates an electrode 200 according to another embodiment of the present application. Electrode 200 comprises a step 220 in the electrode body 102 that corresponds to a step 222 in a base plate liner 224. The base plate liner 224 can be positioned in the base plate 104 of a CVD apparatus. By employing this arrangement, the electrode body 102 can be supported by the base plate liner 224 when the electrode cap 106 is removed.

The base plate liner 224 can be made of any suitable material that can withstand high processing temperatures and still provide structural integrity. Examples of suitable base plate liner materials include stainless steel, nickel alloy, nickel plated steel, nickel plated stainless steel, silver plated steel, and silver plated stainless steel.

The base plate liner 224 can be held in position in the base plate 104 using any desired technique. For example, the base plate liner 224 can comprise a lip 226 and a threaded region 228 capable of attaching to a nut 230. The base plate liner 224 can be held in place on the base plate 104 between the lip 226 and the nut 230, as shown in the embodiment of FIG. 4. Other examples of techniques for holding the base plate liner in place include a friction fit between the base plate liner 224 and base plate 104, or the use of bolts or other fasteners.

As illustrated in FIG. 4, an electrical isolation layer 110 can be employed between the base plate liner 224 and the electrode 200. The electrical isolation layer 110 is similar to the isolation layer of the embodiment of FIG. 3, except that it includes a step corresponding to steps 220 and 222.

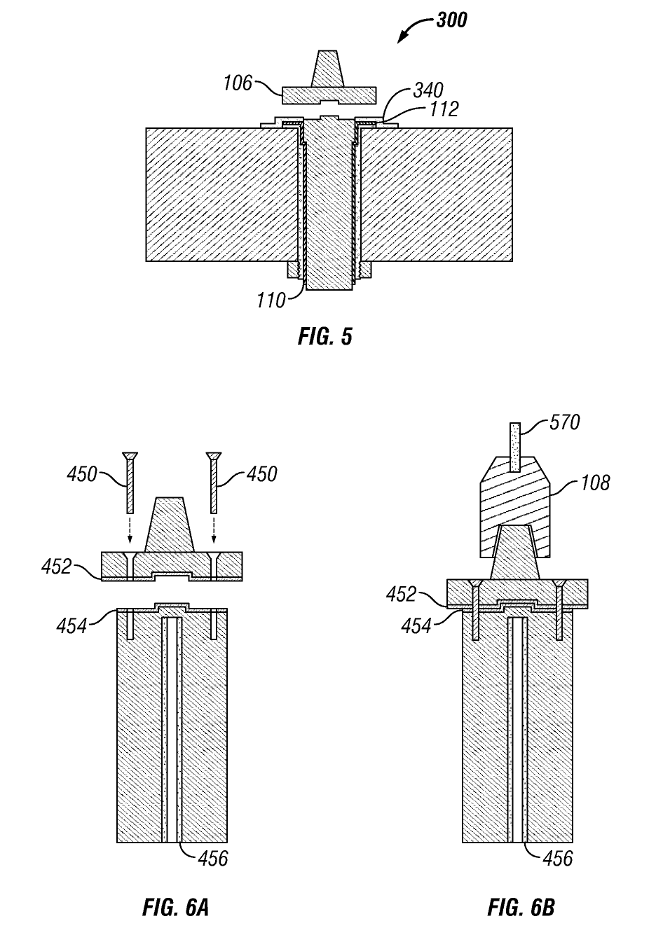

FIG. 5 illustrates an electrode 300, according to an embodiment of the present disclosure. Electrode 300 is similar to the electrode 200 of FIG. 4, as described above, except that electrode 300 includes a voltage isolation ring 340 positioned between the electrode cap 106 and the base plate 104. Voltage isolation ring 340 can be used in addition to the ring portion 112 of the isolation layer 110. This can provide for added electrical insulation between the electrode cap 106 and the base plate 104. The thickness and width of the voltage isolation ring 340 can vary depending on the voltage levels employed, with thicker and wider ring dimensions being employed for high voltage applications. Further, the configuration shown in FIG. 5 can allow the voltage isolation ring 340 to be easily replaced by simply removing the electrode cap 106.

FIGS. 6A and 6B illustrate an example technique for attaching the electrode cap 106 to the electrode body 102 by using fasteners 450, which can be bolts or screws. Any other suitable fastening techniques can be used. For example, fasteners 450 can be clamps or other fasteners known in the art.

As also illustrated in FIGS. 6A and 6B, electrical conducting layers 452 and 454 can be positioned between the electrode body 102 and the electrode cap 106, according to an embodiment of the present disclosure. While both electrical conducting layers 452 and 454 are shown, a single electrical conducting layer can instead be applied to either the electrode body 102 or the electrode cap 106. The electrical conducting layers can be employed to provide improved electrical conductivity and/or heat conductance properties between the electrode body 102 and the electrode cap 106.

Electrical conducting layers can be formed by any suitable techniques, such as by electroplating or sintering in the contact area between the electrode body 102 and the electrode cap 106. Examples of materials that can be used as a conducting layer include silver, silver alloys, nickel, nickel alloys, tin, tin alloys, gold and gold alloys. Any other suitable materials that can provide the desired electrical and heat conducting properties at high temperature processing conditions can be used.

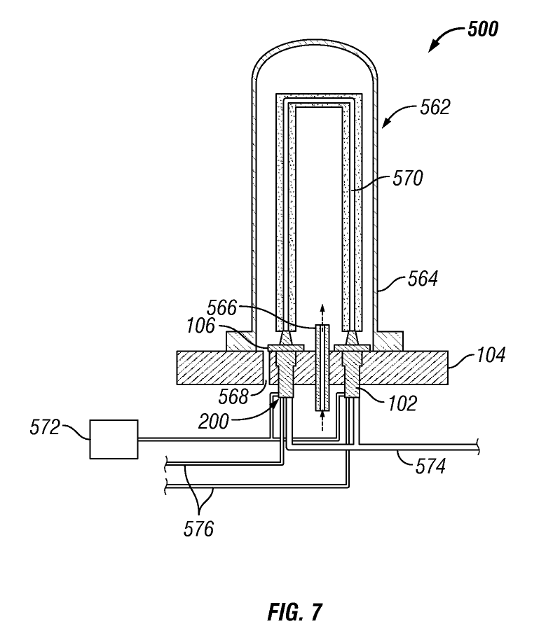

Any of the above described electrodes of the present application can be employed in any suitable chemical vapor deposition apparatus. An example of a suitable chemical vapor deposition apparatus 500 is illustrated in FIG. 7. The CVD apparatus 500 includes a chamber 562 comprising a base plate 104, a chamber wall 564, a gas inlet 566 and a gas outlet 568. A plurality of electrodes 200 each comprise an electrode body 102 and an electrode cap 106 removably attached to the body 102. The electrode body 102 can be positioned through the base plate 104. The cap 106 can be positioned inside the chamber 562. A silicon rod 570 can be electrically coupled to at least two electrodes 200 in the chamber 564. While only a single silicon rod 570 is illustrated, the chamber 562 can include a plurality of silicon rods 570, as is well known in the art. An adapter 108 (FIG. 6B) can be positioned between the silicon rod 570 and each electrode 200. A power source 572 can be attached to the plurality of electrodes, as is also well known in the art.

The electrodes of the present application can be liquid cooled electrodes. FIG. 7 illustrates coolant conduits 574 and 576, which can be employed for flowing a coolant, such as water, to and from the electrodes 200. The electrodes can be designed to have internal coolant flow paths 456, as schematically illustrated in FIG. 6, to provide the desired cooling. Examples of electrodes designed with coolant flow configurations are also taught in U.S. patent application Ser. No. 12/270,981, which was filed by Jui Hai Hsieh, the inventor of the current application, on Nov. 14, 2008, the disclosure of which is hereby incorporated by reference in its entirety.

The present disclosure is also directed to a method of repairing the above described electrodes in a chemical vapor deposition apparatus. The method comprises removing the electrode cap from the electrode body. A new electrode cap can then be attached to the electrode body to replace the damaged electrode cap. If the electrode includes a voltage isolation ring positioned under the electrode cap, the voltage isolation ring can be replaced with a new isolation ring after removing the electrode cap. The electrode body 102 can remain positioned in the chemical vapor deposition apparatus during at least a portion of the time that the electrode cap 106 is removed from the body 102.

Although various embodiments have been shown and described, the disclosure is not so limited and will be understood to include all such modifications and variations as would be apparent to one of ordinary skill in the art.

What is claimed is:

1. A chemical vapor deposition apparatus, comprising:
a chamber having a base plate, a chamber wall, a gas inlet and a gas outlet;
a plurality of electrodes each comprising an electrode body and an electrode cap removably attached to the body, the electrode body positioned through the base plate and the cap being positioned inside the chamber; and
an electrical isolation layer positioned between the electrode and the base plate;
wherein the plurality of electrodes are capable of being attached to a power source; and
wherein at least two of the plurality of electrodes are capable of being electrically coupled to a silicon rod positioned in the chamber.

2. The chemical vapor deposition apparatus of claim 1, wherein the silicon rod is attached to the at least two electrodes, and further comprising an adapter positioned between the silicon rod and each electrode.

3. The chemical vapor deposition apparatus of claim 1, wherein the electrical isolation layer is PTFE.

4. The chemical vapor deposition apparatus of claim 3, wherein the electrical isolation layer comprises an isolation ring portion positioned between the electrode cap and the base plate.

5. The chemical vapor deposition apparatus of claim 4, further comprising a voltage isolation ring in addition to the electrical isolation ring portion, the voltage isolation ring also being positioned between the electrode cap and the base plate.

6. The chemical vapor deposition apparatus of claim 1, further comprising a base plate liner positioned between the electrical isolation layer and the base plate.

7. The chemical vapor deposition apparatus of claim 6, wherein the base plate liner comprises a first step configured to support the weight of the electrode.

8. The chemical vapor deposition apparatus of claim 7, wherein the body of the electrode comprises a step that is configured to support the weight of the electrode, the electrode body step being configured to rest upon the base plate liner step.

9. The chemical vapor deposition apparatus of claim 1, further comprising an electrical conducting layer positioned between the electrode body and the electrode cap.

10. The chemical vapor deposition apparatus of claim 9, wherein the electrical conducting layer comprises a material chosen from silver, silver alloys, tin, tin alloys, nickel, nickel alloys, gold, and gold alloys.

11. A vertical stand electrode comprising:
an electrode body; and
an electrode cap removably attached to the body.

12. The electrode of claim 11, further comprising a graphite adapter positioned on the electrode cap.

13. The electrode of claim 11, wherein electrode body is cylindrically shaped.

14. The electrode of claim 13, further comprising an electrical isolation layer positioned around the electrode body.

15. The electrode of claim 14, wherein the electrical isolation layer is PTFE.

16. The electrode of claim 11, wherein the electrode body comprises a step that is configured to support the weight of the electrode.

17. The electrode of claim 11, further comprising an electrical conducting layer positioned between the electrode body and the electrode cap.

18. The electrode of claim 17, wherein the electrical conducting layer comprises a material chosen from silver, silver alloys, tin, tin alloys, nickel, nickel alloys, gold, and gold alloys.

19. The electrode of claim 11, wherein the cap is fastened to the electrode body with at least one fastener chosen from bolts, screws and clamps.

20. The electrode of claim 11, wherein the electrode is configured to be liquid cooled.

21. A method of repairing an electrode in a chemical vapor deposition apparatus, the electrode comprising an electrode body positioned in the chemical vapor deposition apparatus and an electrode cap removably attached to the body, the method comprising:
removing the electrode cap from the electrode body; and
attaching a new electrode cap to the electrode body.

22. The method of claim 21, wherein the electrode further comprises a voltage isolation ring positioned under the electrode cap, the method further comprising replacing the voltage isolation ring with a new isolation ring after removing the electrode cap.

23. The method of claim 21, wherein the electrode body remains positioned in the chemical vapor deposition apparatus during at least a portion of the time that the electrode cap is removed.
